(19) United States
(12) Patent Application Publication
(10) Pub. No.: US 2003/0197215 A1
(43) Pub. Date: Oct. 23, 2003

(54) A DUAL STACKED METAL-INSULATOR-METAL CAPACITOR AND METHOD FOR MAKING SAME

(75) Inventors: Douglas Duane Coolbaugh, Essex Junction, VT (US); Alvin Jose Joseph, Williston, VT (US); John Chester Malinowski, Jericho, VT (US); Vidhya Ramachandran, Colchester, VT (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY

(21) Appl. No.: 10/248,658

(22) Filed: Feb. 5, 2003

Related U.S. Application Data
(60) Provisional application No. 60/354,882, filed on Feb. 5, 2002.

(51) Int. Cl. H01L 27/108

(52) U.S. Cl. 257/306

(57) ABSTRACT

A multilayer semiconductor device and method of making a dual stacked metal-insulator-metal (MIM) capacitor of a multilayer semiconductor device, which includes a bottom metal layer including a capacitor plate and a wiring level, an intermediate metal layer forming at least a capacitor plate, and a top metal layer including a capacitor plate and a wiring level, a via that electrically contacts the intermediate metal layer, and at least two electrically connected vias that contact the bottom metal layer and the top metal layer. A dielectric etchstop layer may be formed above the dual stacked MIM capacitor.

### CROSS REFERENCE TO RELATED APPLICATIONS

This application is based on Provisional Application No. 60/354,882, filed on Feb. 5, 2002.

### BACKGROUND OF THE INVENTION

1. Field of the Invention

The present invention generally relates to a dual stacked metal-insulator-metal (MIM) capacitor of a multilayer semiconductor device and a method of fabricating the same. More particularly, this invention relates to a dual stacked MIM capacitor, in which a bottom metal layer, including a metal plate of a first capacitor and a wiring level, and a top metal layer, including a metal plate of a second capacitor and a wiring level, are electrically connected to form a first terminal of the dual stacked MIM capacitor, while an intermediate metal layer forms a metal plate for both the first and the second capacitors and a second terminal of the dual stacked MIM capacitor.

2. Description of the Related Art

The fabrication of semiconductor devices would benefit from increasing the capacity density of MIM capacitors because a greater capacity density yields a higher capacitance per unit of chip area. This higher capacitance per unit of chip area would allow MIM capacitors to have a smaller area, which permits greater compacting of semiconductor chips through space savings.

Conventionally, an MIM capacitor of a multilayer semiconductor device is formed by depositing on a substrate, a bottom metal layer, a portion of which forms a bottom metal plate of the MIM capacitor and another portion of which forms an electrical contact area, depositing a dielectric layer on the bottom metal plate, and depositing on the dielectric layer, a metal top layer, a portion of which forms a top metal plate of the MIM capacitor and another portion of which forms an electrical contact area. Over the MIM capacitor, a dielectric is deposited through which vias are formed to contact the electrical contact areas of the bottom metal layer and the top metal layer.

In a multilayer semiconductor device, when vias are formed to contact the metal plates of an MIM capacitor, greater control of forming the vias and maintaining a shape of the via are obtained by using an anisotropic etch process, such as, reactive ion etching (RIE), as opposed to an isotropic etching process, such as, a wet chemical etch. RIE is particularly useful for forming vias when the depth and corresponding aspect ratio of the via are relatively large. However, forming vias that contact the capacitor plates of an MIM capacitor by RIE and other anisotropic etch processes, which use ions and/or plasma, can produce degradation of the capacitor's dielectric and even plate-to-plate electrical shorting of the MIM capacitor.

Dielectric breakdown is caused by excessive electrical charge build-up across the plates, which may result from an aggressive RIE etch that lands a via on the top plate of the MIM capacitor or other anisotropic etch processes that are performed at levels above the MIM capacitor. Dielectric breakdown results from permanent conductive channels being formed in the dielectric, which degrade the insulative properties of the dielectric.

Plate-to-plate electrical shorting of an MIM capacitor results from either top plate etch-through by an aggressive RIE etch that lands on the top plate or by dielectric breakdown caused by aggressive anisotropic etching above the MIM capacitor that causes electrical shorting across the dielectric layer.

A higher capacitance per unit of chip area is achieved by vertically stacking MIM capacitors in a multilayer semiconductor device. In stacking, the bottom metal plate and the top metal plate of a first MIM capacitor, respectively, are electrically connected in parallel to another bottom metal plate and another top metal plate of a second MIM capacitor, which is stacked above the first MIM capacitor. Thus, two conventionally stacked MIM capacitors have four metal plates.

Two conventionally stacked MIM capacitors are built on two consecutive metal levels, adding cost to the fabrication process. Four metal plates imply four different photolithography steps for patterning the two conventionally stacked MIM capacitors and an additional via level between them to connect the two conventionally stacked MIM capacitors appropriately. Thus, the fabrication of the two conventionally stacked MIM capacitors incurs the added costs of five lithography levels and one via processing level in order to double the capacitance density by stacking two MIM capacitors.

Semiconductor technology would greatly benefit from an MIM capacitor that provides the higher capacitance per unit of chip area of two conventionally stacked MIM capacitors, while simplifying the structure by reducing the number of metal and via layers, and thus, decreasing process complexity and cost, e.g., the number of steps and the number of masks used.

### BRIEF SUMMARY OF THE INVENTION

In view of the foregoing and other problems and disadvantages of two conventionally stacked MIM capacitors, an advantage of the present invention is a dual stacked MIM capacitor, which may provide a capacitance comparable to two conventionally stacked MIM capacitors, but that allows the number of metal layers to be decreased.

Another advantage of the present invention may be decreasing the complexity and cost of fabrication of a dual stacked MIM capacitor by reducing the number of fabrication steps and the number of masks used in the fabrication steps.

Another advantage of the present invention is that an extended lifetime of the dual stacked MIM capacitor may be attained by depositing a dielectric etchstop layer above the dual stacked MIM capacitor to prevent degradation of the dual stacked MIM capacitor's dielectrics, which may be caused by excessive electrical charging and ion/plasma damage of the metal layers of the dual stacked MIM capacitor by anisotropic etch processes.

Another advantage of the present invention is preventing plate-to-plate electrical shorting of the dual stacked MIM capacitor, which may be caused by either top and/or intermediate plate etch-through or dielectric breakdown, associated with anisotropic etch processes above the level of either or both of the MIM capacitors forming the dual stacked MIM capacitor.

In order to attain the above and other advantages, according to an exemplary embodiment of the present invention, disclosed herein is a multilayer semiconductor device that comprises a dual stacked metal-insulator-metal (MIM) capacitor, which includes a bottom metal layer including a capacitor plate and a wiring level, an intermediate metal layer forming at least a capacitor plate, and a top metal layer including a capacitor plate and a wiring level, a via that electrically contacts the intermediate metal layer, and at least two vias, which are electrically connected, that contact the bottom metal layer and the top metal layer.

According to another exemplary embodiment of the present invention, the dual stacked MIM capacitor further comprises a first dielectric layer located between the bottom metal layer and the intermediate metal layer, and a second dielectric layer located between the intermediate metal layer and the top metal layer.

According to another exemplary embodiment of the present invention, the multilayer semiconductor further comprises an interlayer dielectric formed on the dual stacked MIM capacitor through which the via and the at least two vias are formed.

According to another exemplary embodiment of the present invention, the bottom metal layer, the intermediate metal layer, and the top metal layer comprise at least one of aluminum, copper, tungsten, titanium, tantalum, nitrides of titanium and tantalum, and other transition metals and alloys of these transition metals.

According to another exemplary embodiment of the present invention, a dielectric etchstop layer is deposited below the interlayer dielectric and above the dual stacked MIM capacitor.

According to another exemplary embodiment of the present invention, a thin interlayer dielectric is formed between the top metal layer and the dielectric etchstop layer.

According to another exemplary embodiment of the present invention, the thickness of the dielectric etchstop layer is about 500 âₙ<< to about 1500 âₙ<<.

According to another exemplary embodiment of the present invention, the multilayer semiconductor further comprises a patterned metal level disposed on top surfaces of the interlayer dielectric, the via that electrically contacts the intermediate metal layer and the at least two vias that contact the bottom metal layer and the top metal layer.

According to another exemplary embodiment of the present invention, the patterned metal level comprises at least two unconnected portions, such that, one portion of the patterned metal level contacts the via and another unconnected portion contacts the at least two vias.

According to another exemplary embodiment of the present invention, the at least two vias are electrically connected by the another unconnected portion of the patterned metal level.

According to another exemplary embodiment of the present invention, a method of fabricating a multilayer semiconductor device comprises forming a stack, including a top metal layer, an intermediate metal layer, and a bottom metal layer, on a substrate, patterning the top metal layer, a portion of which forms a metal plate of a first metal-insulator-metal (MIM) capacitor, patterning the intermediate metal layer, a portion of which forms a metal plate that acts as a metal plate for the first MIM capacitor and for a second MIM capacitor, patterning the bottom metal layer, a portion of which forms a metal plate of the second MIM capacitor, to form a dual stacked MIM capacitor, forming by an anisotropic etch process, a via that contacts the patterned intermediate metal layer and at least two vias that contact the patterned top metal layer and patterned bottom metal layer, and electrically connecting the at least two vias.

According to another exemplary embodiment of the present invention, he method further comprising forming a first dielectric layer between the bottom metal layer and the intermediate metal layer of the stack, and forming a second dielectric layer between the intermediate metal layer and the top metal layer of the stack.

According to another exemplary embodiment of the present invention, the method further comprising forming a metal level on top surfaces of the interlayer dielectric, the via, and the at least two vias, in which the metal level comprises at least two unconnected portions.

According to another exemplary embodiment of the present invention, one portion of the at least two unconnected portions of the metal level forms a first terminal of the dual stacked MIM capacitor, which is electrically connected by the via to the intermediate metal level, and another portion of the at least two unconnected portions of the metal level forms a second terminal of the dual stacked MIM capacitor, which is electrically connected by the at least two vias to the top metal layer and the bottom metal layer.

According to another exemplary embodiment of the present invention, a method of fabricating a multilayer semiconductor device that comprises forming a stack, including a top metal layer, an intermediate metal layer, and a bottom metal layer, on a substrate, patterning the top metal layer, a portion of which forms a-metal plate of a first metal-insulator-metal (MIM) capacitor, patterning the intermediate metal layer, a portion of which forms a metal plate that acts as a metal plate for the first MIM capacitor and for a second MIM capacitor, patterning the bottom metal layer, a portion of which forms a metal plate of the second MIM capacitor, to form a dual stacked MIM capacitor, depositing a dielectric etchstop layer on the dual stacked MIM capacitor, forming by an anisotropic etch process, a via that contacts a portion of the dielectric etchstop layer on the patterned intermediate metal layer and at least two vias that contact portions of the dielectric etchstop layer on the patterned top metal layer and bottom metal layer, and electrically connecting the at least two vias.

According to another exemplary embodiment of the present invention, the patterned metal level comprises at least two unconnected portions, such that, one portion of the patterned metal level contacts the via and another unconnected portion contacts the at least two vias.

According to another exemplary embodiment of the present invention, the method further comprising removing portions of the dielectric etchstop layer, where the via and the at least two vias contact the dielectric etchstop layer on the patterned intermediate layer and the patterned top metal layer and bottom metal layer, respectively.

According to another exemplary embodiment of the present invention, removing the portions of the dielectric etchstop layer is accomplished by a selective via etch chemistry that includes a wet etch or a dry reactive ion etch including any of argon, nitrogen, C₄F₈ and argon or oxygen, and carbon monoxide.

According to another exemplary embodiment of the present invention, the method further comprising forming a thin dielectric layer between the top metal layer and the dielectric etchstop layer.

According to another exemplary embodiment of the present invention, the method of further comprising forming a metal level on an interlayer dielectric layer, which is formed on the dielectric etchstop layer and through which the via and the at least two vias are formed, in which the metal level comprises at least two unconnected portions, one portion of which forms a first terminal of the dual stacked MIM capacitor, which is electrically connected by the via to the intermediate metal level, and another unconnected portion of which forms a second terminal of the dual stacked MIM capacitor, which is electrically connected by the at least two vias to the top metal layer and the bottom metal layer.

Thus, the present invention overcomes the disadvantages of the structure and method of fabricating two conventionally stacked MIM capacitors by providing a capacitance comparable to that of two conventionally stacked MIM capacitors, but with fewer metal layers, which decreases fabrication complexity. The present invention may also yield an extended lifetime of the dual stacked MIM capacitor, which may be attained by depositing an optional dielectric etchstop layer above the dual stacked MIM capacitor to prevent degradation of the dual stacked MIM capacitor's dielectrics by excessive electrical charging and ion/plasma damage of the metal layers of the dual stacked MIM capacitor by anisotropic etch processes.

### BRIEF DESCRIPTION OF THE SEVERAL VIEWS OF THE DRAWINGS

### Brief Description of the Drawings

The foregoing and other aspects and advantages will be better understood from the following detailed description of a preferred embodiment of the invention with reference to the drawings, in which:

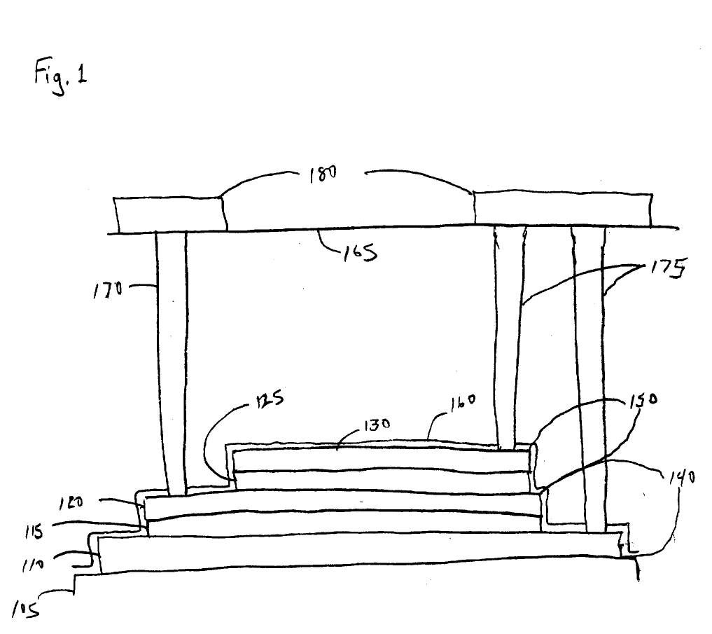

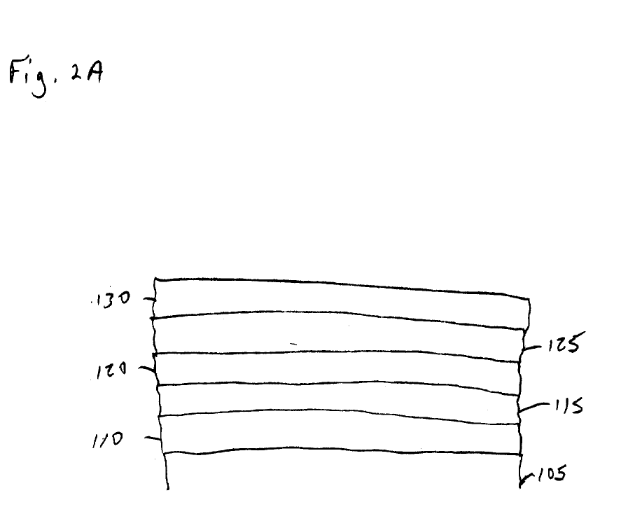

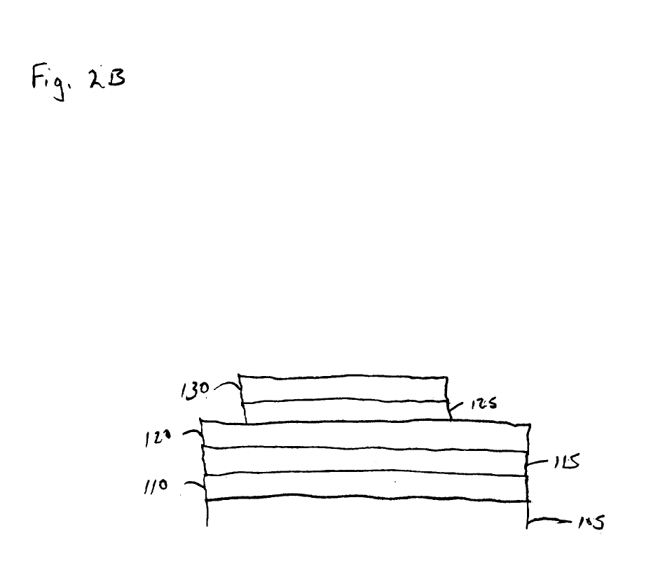

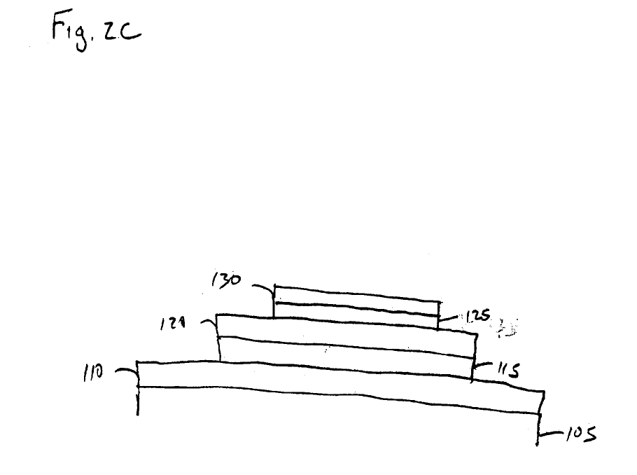

FIG. 1 illustrates a schematic cross-section of a dual stacked MIM capacitor 100 in an exemplary embodiment of the present invention;

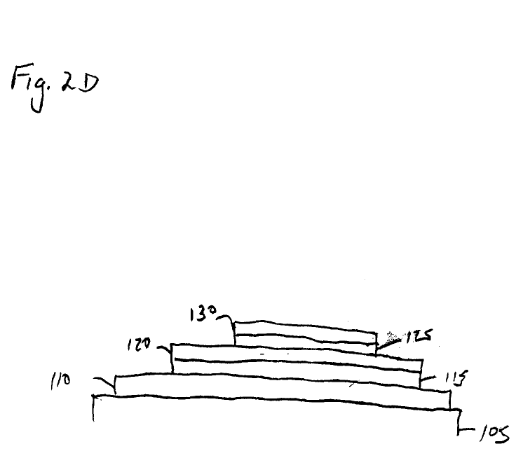

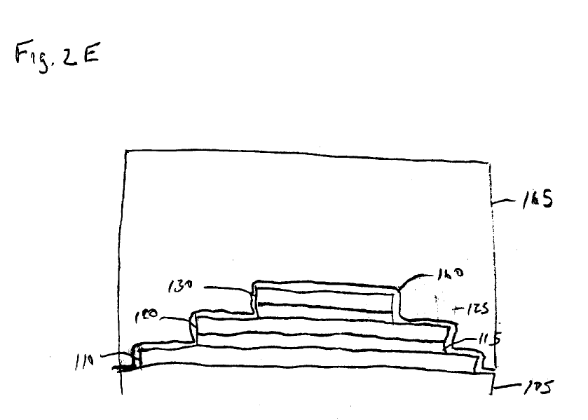

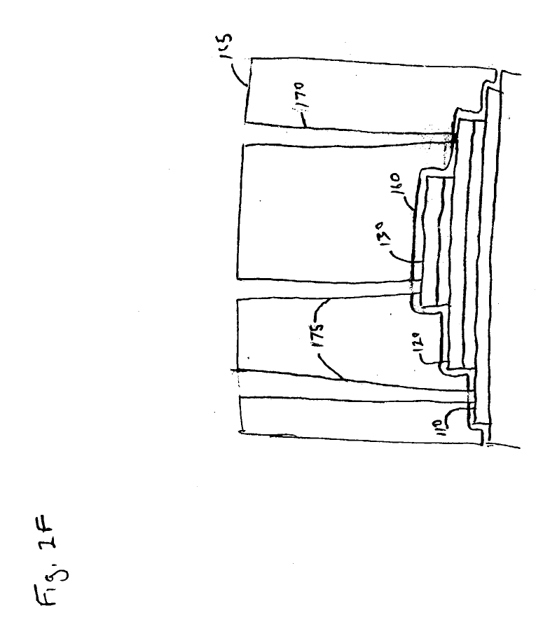

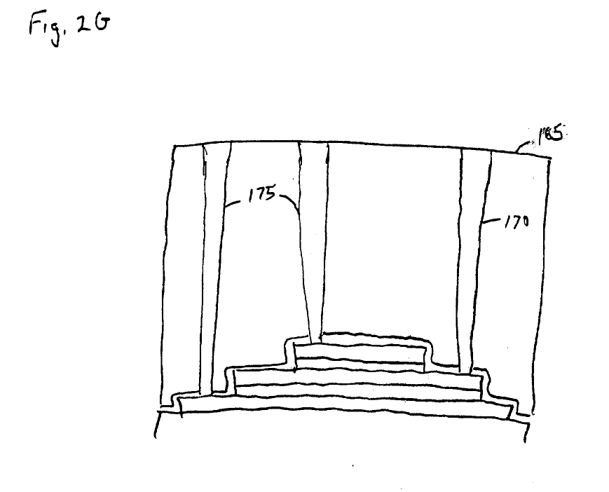

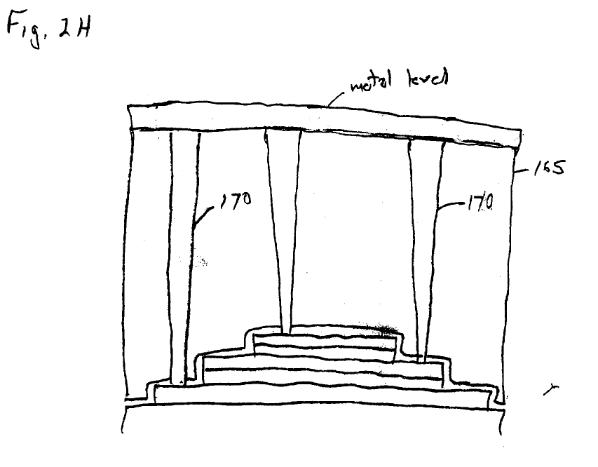

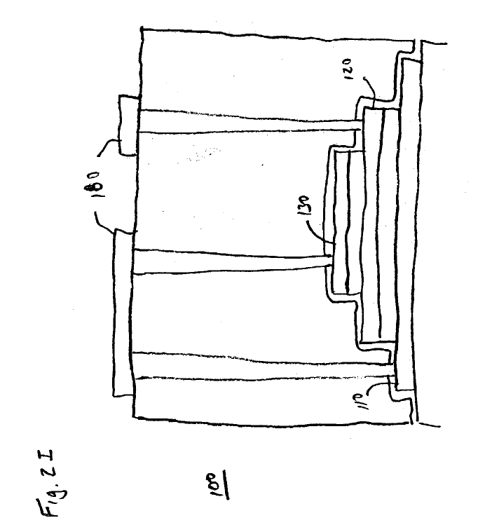

FIG. 2A illustrates deposition of a stack in the fabrication of the dual stacked MIM capacitor 100 of FIG. 1 in an exemplary embodiment of the present invention;

FIG. 2B illustrates patterning of a top metal layer of the dual stacked MIM capacitor 100 of FIG. 1 in an exemplary embodiment of the present invention;

FIG. 2C illustrates patterning of an intermediate metal layer of the dual stacked MIM capacitor 100 of FIG. 1 in an exemplary embodiment of the present invention;

FIG. 2D illustrates patterning of a bottom metal layer of the dual stacked MIM capacitor 100 of FIG. 1 in an exemplary embodiment of the present invention;

FIG. 2E illustrates deposition of a dielectric etchstop layer and an interlayer dielectric of the dual stacked MIM capacitor 100 of FIG. 1 in an exemplary embodiment of the present invention;

FIG. 2F illustrates formation of a via through the interlayer dielectric to a portion of the dielectric etchstop layer, located above the intermediate metal layer, and of at least two vias through the interlayer dielectric to those portions of the dielectric etchstop layer, located above the bottom metal layer and the top metal layer, respectively, of the dual stacked MIM capacitor 100 of FIG. 1 in an exemplary embodiment of the present invention;

FIG. 2G illustrates filling of the via and the at least two vias with an electrical conductor and flattening the top surfaces of the interlayer dielectric and the via and the at least two vias of the dual stacked MIM capacitor 100 of FIG. 1 in an exemplary embodiment of the present invention;

FIG. 2H illustrates deposition of a metal level on the flattened top surface of the interlayer dielectric and the top surfaces of the via and the at least two vias of the dual stacked MIM capacitor 100 of FIG. 1 in an exemplary embodiment of the present invention;

FIG. 2I illustrates patterning of the metal level to form a patterned metal level with at least two unconnected portions of the dual stacked MIM capacitor 100 of FIG. 1 in an exemplary embodiment of the present invention; and

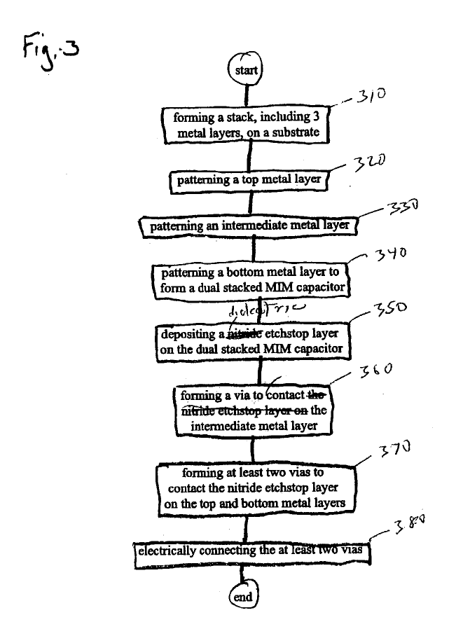

FIG. 3 illustrates a flowchart of a method for fabricating the dual stacked MIM capacitor 100 of the multilayer semiconductor device of FIG. 1 in an exemplary embodiment of the present invention.

### DETAILED DESCRIPTION OF THE INVENTION

Generally, the present invention takes advantage of a bottom metal layer and a top metal layer, which are electrically connected together to form one terminal of a dual stacked MIM capacitor, and a single intermediate metal layer, which forms the other terminal of the dual stacked MIM capacitor. The dual stacked MIM capacitor of the present invention may provide the capacity density of two conventionally stacked MIM capacitors, with fewer metal layers.

In various exemplary embodiments, deposition of a dielectric etchstop layer may occur after patterning the metal layers of the dual stacked MIM capacitor, and optionally, after a thin intervening interlayer dielectric may be deposited between the patterned metal layers and the dielectric etchstop layer.

Referring to FIG. 1, a bottom metal layer 110, a portion of which forms a metal plate of a first MIM capacitor 140 of the dual stacked MIM capacitor 100 and another portion of which forms a wiring level, may be formed on a substrate 105. The another portion of the bottom metal layer 110, which forms a wiring level, may be electrically connected to another wiring level of another layer by a via.

The bottom metal layer 110 may comprise aluminum, copper, tungsten, titanium, tantalum, nitrides of titanium and tantalum, and other transition metals and alloys of these transition metals well known in the art. The bottom metal layer 110 may have a thickness of about 500 âₙ<< to about 15,000 âₙ<<. The portion of the bottom metal layer 110, which forms a metal plate of the first MIM capacitor 140, may have an area of about 0.0001 mm² to about 1 mm².

A first dielectric layer 115 may be formed over the bottom metal layer 110. The first dielectric layer 115 may comprise of silicon oxide, silicon nitride, silicon oxynitride, tantalum pentoxide, aluminum oxide, titanium oxide, UV nitride, i.e., a silicon nitride that is transparent to UV radiation, silicon carbide, and other dielectric materials well known in the art. The first dielectric layer 115 may have a thickness of about 50 âₙ<< to about 1200 âₙ<<.

An intermediate metal layer 120, a portion of which forms a metal plate that acts as a metal plate for both the first MIM capacitor 140 and the second MIM capacitor 150 of the dual stacked MIM capacitor 100 and another portion of which forms an area of electrical contact, may be formed on the first dielectric layer 115. The another portion of the intermediate metal layer 120, which forms an area of electrical contact, may be electrically connected to another wiring level of another layer by a via.

The intermediate metal layer 120 may comprise aluminum, copper, tungsten, titanium, tantalum, nitrides of titanium and tantalum, and other transition metals and alloys of these transition metals well known in the art. The intermediate metal layer 120 may have a thickness of about 500 âₙ<< to about 15,000 âₙ<<.

A second dielectric layer 125 may be formed over the intermediate metal layer 120. The second dielectric layer 125 may comprise silicon oxide, silicon nitride, silicon oxynitride, tantalum pentoxide, aluminum oxide, titanium oxide, UV nitride, silicon carbide and other dielectric materials well known in the art. The second dielectric layer 115 may have a thickness of about 50 âₙ<< to about 1200 âₙ<<.

A top metal layer 130, a portion of which forms a metal plate of the second MIM capacitor 150 of the dual stacked MIM capacitor 100 and another portion of which forms a wiring level, may be formed on the second dielectric layer 125. The another portion of the top metal layer 130, which forms a wiring level, may be electrically connected to another wiring level of another layer by a via.

The top metal layer 130 may comprise aluminum, copper, tungsten, titanium, tantalum, nitrides of titanium and tantalum, and other transition metals and alloys of these transition metals well known in the art. The top metal layer 130 may have a thickness of about 500 âₙ<< to about 15,000 âₙ<<.

Optionally, a dielectric etchstop layer 160 may be formed above the dual stacked MIM capacitor. In various exemplary embodiments, the thickness of the dielectric etchstop layer 160 may be from about 500 âₙ<< to about 1500 âₙ<<, with a preferred thickness of about 700 âₙ<<.

An interlayer dielectric 165 may be formed above the dual stacked MIM capacitor or optionally, above the dielectric etchstop layer 160. The interlayer dielectric 165 may comprise silicon oxide, fluorinated silicon oxide, SiLK, and other dielectric materials well known in the art. The interlayer dielectric 165 may have a thickness greater than about 3000 âₙ<<.

Referring to FIG. 1, a via 170 may be formed through the interlayer dielectric 165 to the intermediate metal layer 120 or optionally, to a portion of the dielectric etchstop layer 160 located above the intermediate metal layer 120. At least two vias 175 may be formed through the interlayer dielectric 165 to the bottom metal layer 110 and the top metal layer 130, respectively, or optionally, to those portions of the dielectric etchstop layer 160 located above the bottom metal layer 110 and the top metal layer 130, respectively. Where the via 170 contacts the dielectric etchstop layer 160 above the intermediate metal layer 120 and the at least two vias 175 contact the dielectric etchstop layer above the bottom metal layer 110 and the top metal layer 130, corresponding portions of the dielectric etchstop layer 160 may be removed.

A patterned metal level 180 may be formed on the interlayer dielectric 165. The patterned metal layer 180 may include at least two unconnected portions, in which one portion also fills the via 170, and in which another unconnected portion also fills the at least two vias 175, with a conductor. Alternatively, the via 170 and the at least two vias 175 may be filled with an electrical conductor and the patterned metal level 180 deposited on the interlayer dielectric 165, such that, one portion of the patterned metal level 180 contacts the via 170 and another unconnected portion contacts the at least two vias 175.

The patterned metal level 180 may comprise aluminum, copper, a combination of aluminum and copper, tungsten, or other transition metals and transition metal alloys well known in the art.

The at least two unconnected portions of the patterned metal level 180 may correspond to terminals of the dual stacked MIM capacitor 100, such that, the bottom metal layer 110 and the top metal layer 130 are electrically connected in parallel to form a first terminal of the dual stacked MIM capacitor 100, while the intermediate metal layer 120 forms a second terminal of the dual stacked MIM capacitor 100.

FIGS. 2A-I, the methods of fabricating the dual stacked MIM capacitor 100 of FIG. 1 in various exemplary embodiments.

FIG. 2A illustrates, for example, a stack, which is formed on a substrate 105, and which is formed by the sequential depositions of a bottom metal layer 110, a first dielectric layer 115, an intermediate metal layer 120, a second dielectric layer 125, and a top metal layer 130. The bottom metal layer 110, the intermediate metal layer 120, and the top metal layer 130 may be deposited, respectively, on the substrate 105, the first dielectric layer 115, and the second dielectric layer 125 by, for example, sputtering, plating, polishing, and other metal deposition processes well known in the art. The first dielectric layer 115 and the second dielectric layer 125 may be deposited, respectively, over the bottom metal layer 110 and the intermediate metal layer 120 by conventional deposition processes, for example, chemical vapor deposition (CVD), plasma enhanced CVD, atomic layer CVD, organometallic CVD, and other dielectric deposition processes well known in the art.

FIG. 2B illustrates, for example, patterning of the top metal layer 130 by conventional photolithography or by anisotropic etch processes, such as, RIE. Further, the top metal layer 130 may be patterned to form a portion, which forms a metal plate of the second MIM capacitor 150, and another portion, which forms a wiring level. The second dielectric layer 125 may be partially patterned at the same time as patterning of the top metal layer 130.

FIG. 2C illustrates, for example, patterning of the intermediate metal layer 120 by conventional photolithography or by anisotropic etch processes, such as, RIE. Further, the intermediate metal layer 120 may be patterned to form a portion, which forms a single metal plate that acts as a metal plate for both the second MIM capacitor 150 and the first MIM capacitor 140, and another portion, which forms an area of electrical contact. The remaining thickness of the second dielectric layer 125 may be patterned with the patterning of the intermediate layer.

FIG. 2D illustrates, for example, patterning of the bottom metal layer 110 by conventional photolithography or by anisotropic etch processes, such as, RIE. Further, the bottom metal layer, 110 may be patterned to form a portion, which forms a metal plate of the first MIM capacitor 140, and another portion, which forms a wiring level.

FIG. 2E illustrates, for example, the optional deposition of the dielectric etchstop layer 160 over the patterned top metal layer 130, the second dielectric layer 125, the intermediate metal layer 120, the first dielectric layer 115, and the bottom metal layer 110. In various exemplary embodiments, the dielectric etchstop layer 160 may be formed above the dual stacked MIM capacitor 100 by, for example, plasma enhanced CVD (PECVD), atomic layer CVD, organometallic CVD, or other deposition processes well known in the art.

In various exemplary embodiments, optional deposition of the dielectric etchstop layer 160 may occur, for example, after the bottom metal layer 110 has been patterned or after a relatively thin interlayer dielectric (not shown) of about 1500 âₙ<< to about 10,000 âₙ<< has been deposited on the dual stacked MIM capacitor 100, subsequent to the patterning of all of the layers of the dual stacked MIM capacitor 100.

In addition, FIG. 2E illustrates, for example, the deposition of the interlayer dielectric 165 above the optional dielectric etchstop layer 160 by, for example, CVD, PECVD, and other dielectric deposition process well known in the art. Alternatively, the interlayer dielectric 165 may be deposited above all of the patterned layers of the dual stacked MIM capacitor 100.

FIG. 2F illustrates, for example, formation of a via 170 through the interlayer dielectric 165 to a portion of the dielectric etchstop layer 160, located above the intermediate metal layer 120, and of at least two vias 175 through the interlayer dielectric 65 to those portions of the dielectric etchstop layer 160, located above the bottom metal layer 110 and the top metal layer 130, respectively, by an anisotropic etch process, such as, for example, RIE. Alternatively, the via 170 may be formed through the interlayer dielectric 165 to the intermediate metal layer 120, and the at least two vias 175 may be formed through the interlayer dielectrics 65 to the bottom metal layer 110 and the top metal layer 130, respectively, by an anisotropic etch process, such as, for example, RIE.

After the via 170, which contacts the dielectric etchstop layer 160 above the intermediate metal layer 120, and the at least two vias 175, which contact the dielectric etchstop layer above the bottom metal layer 110 and the top metal layer 130, respectively, are formed, corresponding portions of the dielectric etchstop layer 160 may be removed by a selective via etch chemistry.

The selective via etch chemistry may include a wet etch or a dry reactive ion etch including any of argon, nitrogen, C₄F₈ and argon or oxygen, carbon monoxide, and other via etch chemistries well known in the art, which may remove the corresponding portions of the dielectric etchstop layer 160 without damaging either the first dielectric layer 115 or the second dielectric layer 125 by either excessive electrical charging or ion/plasma damage.

The dielectric etchstop layer 160 presumably provides a surface above the top and intermediate metal layers 130, 120 on which an anisotropic via etch process, for example, RIE, is stopped, thereby, preventing etch-through of the top and/or intermediate metal layers and consequently, plate-to-plate electrical shorting. In addition, the insulative properties of the dielectric etchstop layer 160 presumably prevent excessive electrical charge from reaching the metal layers of the MIM capacitor and consequently causing dielectric degradation.

The benefits of depositing the dielectric etchstop layer 160 on the dual stacked MIM capacitor are improved manufacturing yields and enhanced long term reliability by preventing dielectric degradation or plate-to-plate electrical shorting.

The dielectric etchstop layer 160, which is deposited over the dual stacked MIM capacitor, provides a chemical etchstop layer for the via RIE to stop on, thereby, widening the process window for the via RIE process. The via RIE overetch can now be a less controlled process, which neither incurs the risk of affecting the reliability of the dual stacked MIM capacitor, nor causes etch-through of the top and/or intermediate metal layers, nor allows for too much erosion of the metal layer that the via lands on.

FIG. 2G illustrates, for example, filling of the via 170 and the at least two vias 175 with an electrical conductor. The top surface of the interlayer dielectric 165 and the top surfaces of the via 170 and the at least two vias 175 may be polished to a flat surface by chemical mechanical polishing (CMP) or other flattening processes well known in the art.

FIG. 2H illustrates, for example, the deposition of a metal level on the flattened top surface of the interlayer dielectric 165 and the top surfaces of the via 170 and the at least two vias 175, such that, electrical contacts may be formed between the metal level and the via 170 and the at least two vias 175.

FIG. 2I illustrates, for example, the patterning of the metal level to form a patterned metal level 180. The patterned metal level 180 may be patterned, such that, at least two unconnected portions of the patterned metal level 180 may form the two terminals of the dual stacked MIM capacitor 100. One portion of the patterned metal level 180 may electrically connect the bottom metal layer 110 and the top metal layer 130, to form a first terminal of the dual stacked capacitor 100, while another unconnected portion of the patterned metal level 180 may electrically connect the intermediate metal layer 120 to form a second terminal of the dual stacked capacitor 100.

FIG. 3 illustrates a flowchart of a method for fabricating the dual stacked MIM capacitor 100 of the multilayer semiconductor device. Initially, a stack is formed, including three metal layers, on a substrate, 310. A top metal layer is patterned, 320. An intermediate metal layer is patterned, 330. A bottom metal layer is patterned, 340; thus, forming the dual stacked MIM capacitor. An optional dielectric etchstop layer id deposited on the dual stacked MIM capacitor, 350. A via is formed to contact the intermediate metal layer, 360. At least two vias are formed to contact the top and bottom metal layers, respectively, 370. Finally, the at least to vias are electrically connected, 380.

While the invention has been described in terms of exemplary embodiments, those skilled in the art will recognize that the invention can be practiced with modification within the spirit and scope of the appended claims.

Further, it is noted that Applicants' intent is to encompass equivalents of all claim elements, even if amended later during prosecution.

What is claimed is:

1. A multilayer semiconductor device, comprising:
a dual stacked metal-insulator-metal (MIM) capacitor, including:
a bottom metal layer including a capacitor plate and a wiring level;
an intermediate metal layer forming at least a capacitor plate; and
a top metal layer including a capacitor plate and a wiring level;
a via that electrically contacts the intermediate metal layer; and
at least two electrically connected vias that contact the bottom metal layer and the top metal layer.

2. The multilayer semiconductor device of claim 1, wherein the dual stacked MIM capacitor further comprises:
a first dielectric layer located between the bottom metal layer and the intermediate metal layer; and
a second dielectric layer located between the intermediate metal layer and the top metal layer.

3. The multilayer semiconductor of claim 1 further comprising an interlayer dielectric formed on the dual stacked MIM capacitor through which the via and the at least two electrically connected vias are formed.

4. The multilayer semiconductor of claim 1, wherein the bottom metal layer, the intermediate metal layer, and the top metal layer comprise at least one of aluminum, copper, tungsten, titanium, tantalum, nitrides of titanium and tantalum, and other transition metals and alloys of these transition metals.

5. The multilayer semiconductor of claim 1, wherein a dielectric etchstop layer is deposited below the interlayer dielectric and above the dual stacked MIM capacitor.

6. The multilayer semiconductor of claim 5, wherein a thin interlayer dielectric is formed between the top metal layer and the dielectric etchstop layer.

7. The multilayer semiconductor of claim 5, wherein the thickness of the dielectric etchstop layer is about 500 âₙ<< to about 1500 âₙ<<.

8. The multilayer semiconductor of claim 1, further comprising a patterned metal level disposed on top surfaces of the interlayer dielectric, the via that electrically contacts the intermediate metal layer and the at least two electrically connected vias that contact the bottom metal layer and the top metal layer.

9. The multilayer semiconductor of claim 8, wherein the patterned metal level comprises at least two unconnected portions, such that, a first unconnected portion contacts the via and a second unconnected portion contacts the at least two electrically connected vias.

10. The multilayer semiconductor of claim 9, wherein the at least two electrically connected vias are electrically connected by the second unconnected portion of the patterned metal level.

11. A method of fabricating a multilayer semiconductor device, comprising:
forming a stack, including a top metal layer, an intermediate metal layer, and a bottom metal layer, on a substrate;
patterning the top metal layer, a portion of which forms a metal plate of a first metal-insulator-metal (MIM) capacitor;
patterning the intermediate metal layer, a portion of which forms a metal plate that acts as a metal plate for the first MIM capacitor and for a second MIM capacitor;
patterning the bottom metal layer, a portion of which forms a metal plate of the second MIM capacitor, to form a dual stacked MIM capacitor;
forming by an anisotropic etch process, a via that contacts the patterned intermediate metal layer and at least two vias that contact the patterned top metal layer and patterned bottom metal layer; and
electrically connecting the at least two vias.

12. The method of claim 11, further comprising forming an interlayer dielectric above the dual stacked MIM capacitor through which the via and the at least two vias are formed.

13. The method of claim 11, further comprising forming a metal level on top surfaces of the interlayer dielectric, the via, and the at least two vias,
wherein the metal level comprises at least two unconnected portions.

14. The method of claim 13, wherein one portion of the at least two unconnected portions of the metal level forms a first terminal of the dual stacked MIM capacitor, which is electrically connected by the via to the intermediate metal level, and another portion of the at least two unconnected portions of the metal level forms a second terminal of the dual stacked MIM capacitor, which is electrically connected by the at least two vias to the top metal layer and the bottom metal layer.

15. A method of fabricating a multilayer semiconductor device, comprising:
forming a stack, including a top metal layer, an intermediate metal layer, and a bottom metal layer, on a substrate;
patterning the top metal layer, a portion of which forms a metal plate of a first metal-insulator-metal (MIM) capacitor;
patterning the intermediate metal layer, a portion of which forms a metal plate that acts as a metal plate for the first MIM capacitor and for a second MIM capacitor;
patterning the bottom metal layer, a portion of which forms a metal plate of the second MIM capacitor, to form a dual stacked MIM capacitor;
depositing a dielectric etchstop layer on the dual stacked MIM capacitor; forming by an anisotropic etch process, a via that contacts a portion of the dielectric etchstop layer on the patterned intermediate metal layer and at least two vias that contact portions of the dielectric etchstop layer on the patterned top metal layer and bottom metal layer; and
electrically connecting the at least two vias.

16. The method of claim 15, further comprising:
forming a first dielectric layer between the bottom metal layer and the intermediate metal layer of the stack; and
forming a second dielectric layer between the intermediate metal layer and the top metal layer of the stack.

17. The method of claim 15, further comprising removing portions of the dielectric etchstop layer, where the via and the at least two vias contact the dielectric etchstop layer on the patterned intermediate layer and the patterned top metal layer and bottom metal layer, respectively.

18. The method of claim 17, wherein removing the portions of the dielectric etchstop layer is accomplished by a selective via etch chemistry that includes a wet etch or a dry reactive ion etch including any of argon, nitrogen, C₄F₈ and argon or oxygen, and carbon monoxide.

19. The method of claim 17 further comprising forming a thin dielectric layer between the top metal layer and the dielectric etchstop layer.

20. The method of claim 17, further comprising forming a metal level on an interlayer dielectric layer, which is formed on the dielectric etchstop layer and through which the via and the at least two vias are formed,
wherein the metal level comprises at least two unconnected portions, one portion of which forms a first terminal of the dual stacked MIM capacitor, which is electrically connected by the via to the intermediate metal level, and another unconnected portion of which forms a second terminal of the dual stacked MIM capacitor, which is electrically connected by the at least two vias to the top metal layer and the bottom metal layer.
